(19) United States
(12) Patent Application Publication
(10) Pub. No.: US 2008/0220372 A1
(43) Pub. Date: Sep. 11, 2008

(54) Photosensitive resin composition for black matrix

(76) Inventors: Chun-Hsien Lee, Taichung (TW); Hau-Wei Liao, Jen Te (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/149,696

(22) Filed: May 7, 2008

Related U.S. Application Data
(63) Continuation-in-part of application No. 11/386,732, filed on Mar. 23, 2006.

(51) Int. Cl. G03F 7/004

(52) U.S. Cl. 430/281.1

(57) ABSTRACT

The present invention discloses a photosensitive resin composition for black matrix, which shows no undercut after development. The photosensitive resin composition comprises (A) an alkali-soluble resin, (B) a photopolymerizable monomer, (C) a photoinitiator, (D) a solvent, and (E) a black pigment; wherein the alkali-soluble resin (A) comprises a functional group having a general formula (a-1);

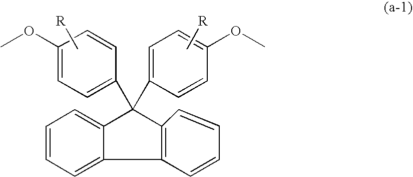

(each R is independently H, linear or branch alkyl of C1-C5, phenyl, or halogen.) wherein a photoinitiator having a general formula (c-1)

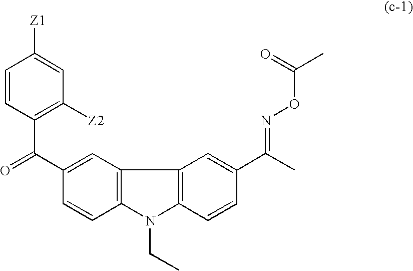

(Z₁ is selected from the group consisting of Ra, Rb—S, Rc-O, wherein each of Ra, Rb, Rc is independently H, alkyl or aryl; Z₂ is H, alkyl of C1-C4, or halide.), wherein the moisture content of said photosensitive resin composition is less than 3,000 ppm, and the optical density value of said black matrixis is greater than 4.0.

### CROSS REFERENCE TO RELATED APPLICATION

This is a Continuation-In-Part application Ser. No. 11/386,732, filed on 23 Mar. 2006.

### BACKGROUND OF THE INVENTION

1. Field of the Invention

The present invention relates to a photosensitive resin composition for black matrix, which is suitable for displays, such as LCD (Liquid Crystal Display) and PDP (Plasma Display). More specifically, the present invention relates to a photosensitive resin composition of showing no undercut and no white dot defect after development.

2. Description of Related Art

In recent years, technologies for promoting resolution and qualities of color filters of LCD have been developed. For example, in order to enhance contrast and related properties, light shielding films are generally formed between stripes and dots of the color filters. Generally, black matrix has been provided as the light shielding films between red, green and blue pixels. Thus high quality of the contrast and hue of LCD can be obtained by shielding light to escape from gaps between the pixels.

The conventional black matrix is formed of chromium by vaporization deposition process. However, such process is complicated and the material used is expensive. A solution for these problems is to apply a new method of using photosensitive resin compositions with photolithography instead of chromium.

There are many patents related to the above-mentioned new method, such as, (1) overlapping red, green and blue layers made of photosensitive resin compositions on substrates, as indicated in Japanese Patent Publication No. 59-204009, No. 63-40101 and No. 2-287303; (2) dyeing specific patterns made of photosensitive resin compositions on substrates, as indicated in Japanese Patent Publication No. 62-14103 and No. 62-14104; and (3) forming patterns made of the photosensitive resin (or photoresist) containing a black pigment (such as carbon black) on substrates, as indicated in Japanese Patent Publication No. 4-177202.

However, the black matrix formed with the above methods (1) and (2) usually results in poor heat resistance and worse light-shielding effect, where as the method (3) has better light-shielding effect when compared with the methods (1) and (2).

As for the method (3), the photosensitive resin composition comprises an alkali-soluble resin as a binder, a photo-acid initiator and a black pigment; wherein the alkali-soluble resin is composed of a phenol resin and a cross linking agent containing N-methylol group. The photosensitive resin composition can form a black matrix through the photolithographic process. In the process, the photosensitive resin composition is first coated on the surface of a glass substrate by spin coating and pre-baked to evaporate the solvent so as to form a pre-baked film. Then, the film is exposed to UV light through a photo mask, and developed with an alkaline solution to dissolve and remove unexposed portions of the film. The desired pattern of the black matrix is obtained after post-bake of the film.

However, the black matrix made according to method (3) has a problem of heat resistance and transparency in the pattern.

A solution for the aforementioned problem is to apply a photosensitive resin composition, which contains a fluorene-based alkali-soluble resin as the binder and a black pigment. The photosensitive resin composition can be coated on substrates to obtain black matrix by employing the photolithographic process, as indicated in U.S. Pat. No. 5,721,076.

However, the higher light shielding is requested in the black matrix of LCD. Generally, it is necessary that the OD (Optical Density) value of black matrix at a thickness of about 1 μm is greater than 2.0. Lately, there are needs for higher quality LCD; especially for the needs of higher contrast of high quality LCD, the OD value is better to be greater than 4.0. But as the described in the U.S. Pat. No. 5,721,076, the photosensitive resin composition contains a fluorene-based alkali-soluble resin as the binder, but it is also necessary to increase the dosage of pigment to reach the OD value (for example, the OD value is greater than 2.0, especially greater than 4.0). Finally, the undercut occurs easily.

As the described in the PCT publication No. WO 02/100903A1, the photosensitive resin composition contains an oxime ester compound as a photoinitiator, but it is also necessary to increase the dosage of pigment to reach the OD value (for example, the OD value is greater than 2.0, especially greater than 4.0). Finally, the undercut occurs easily.

Furthermore, by using a fluorene-based alkali-soluble resin as the binder and an oxime ester compound as a photoinitiator in the photosensitive resin composition for black matrix having high OD value (for example, greater than 4.0), the white dot defect occurred easily after development and resulted in a lower yield of the product.

In recent years, there are requisitions for thinner thickness and higher optical density of the black matrix; the composition mentioned above is still not satisfactory for the needs.

### SUMMARY OF THE INVENTION

The object of the present invention is to provide a photosensitive resin composition for black matrix, which can exhibit no undercut and no white dot defect after development.

### BRIEF DESCRIPTION OF THE TABLE AND DRAWINGS

The preferred embodiments according to the present invention will be set forth in details thereinafter in illustration with the aid of the following table and drawings, wherein:

Table 1 shows formulae and evaluation results of Examples and Comparative Examples.

FIGS. 1 and 2 distinguish edge profiles of the two patterns without and with undercut.

### DETAILED DESCRIPTION OF THE INVENTION

The photosensitive resin composition comprises (A) an alkali-soluble resin comprising a functional group having a general formula (a-1),

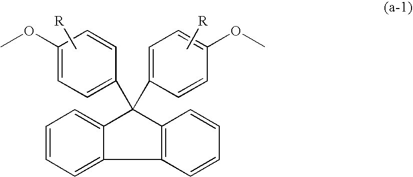

wherein each R is independently H, linear or branch alkyl of C1-C5, phenyl, or halogen; (B) a photopolymerizable monomer; (C) a photoinitiator having a general formula (c-1),

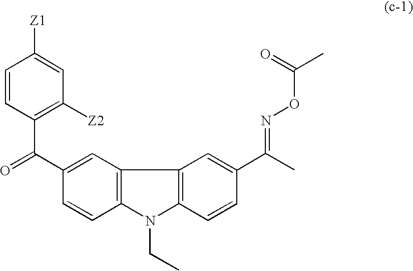

wherein Z₁ is selected from the group consisting of Ra, Rb—S and Rc-O, wherein each of Ra, Rb and Rc is independently H, alkyl or aryl; Z₂ is H, alkyl of C1-C4, or halide; (D) a solvent; and (E) a black pigment, wherein the moisture content of said photosensitive resin composition is less than 3,000 ppm, and the optical density value of black matrix is greater than 4.0.

Each component constituting the present invention will be described below.

### (A) Alkali-Soluble Resin

The alkali-soluble resin (A) in the present invention comprises a functional group having a general formula (a-1), and is formed by polymerizing a compound comprising the functional group having the formula (a-1) and a copolymerizable compound;

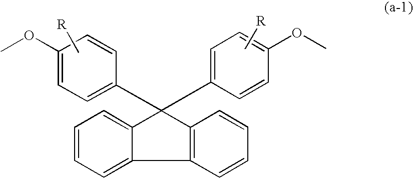

wherein each of R is independently H, linear or branch alkyl of C1-C5, phenyl or halogen.

Examples of the compound comprising the functional group having the formula (a-1) include epoxy or hydroxyl group containing bisphenolfluorene-based compounds which have a general formula (a-2) or (a-3), respectively, and are abbreviated as Compound (a-2) and Compound (a-3);

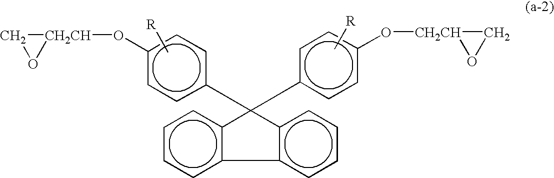

wherein R is defined as the above;

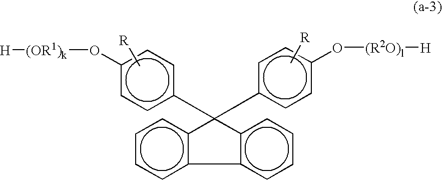

wherein R is defined as the above; R¹, R² are independently selected from alkylene or alicyclic of C1-C20; k, l are independently integers larger than 1.

Examples of the copolymerizable compound aforementioned include unsaturated monocarboxylic acids, such as acrylic acid, methacrylic acid, crotonic acid, α-chloroacrylic acid, ethacrylic acid and cinnamic acid etc.; dicarboxylic acids (or its anhydrides), such as maleic acid, succinic acid, itaconic acid, phthalic acid, tetrahydrophthalic acid, hexahydrophthalic acid, methyl tetrahydrophthalic acid, methyl hexahydrophthalic acid, methyl endo-methylene tetrahydro phthalic acid, chlorendic acid, glutaric acid, etc.; tricarboxylic acids (or its anhydrides), such as trimellitic acid, etc.; and tetracarboxylic acids (or its dianhydrides), such as pyromellitic acid, benzophenone tetracarboxylic acid, biphenyl tetracarboxylic acid, biphenylether tetracarboxylic acid, etc.

The method for producing the alkali-soluble resin (A) of the present invention is not limited, three of which are exemplified as follows:

### Method 1

Compound (a-2) and (meth)acrylic acid are first reacted to produce bisphenolfluroene-based epoxy(meth)acrylate (abbreviated as Compound (a-4));

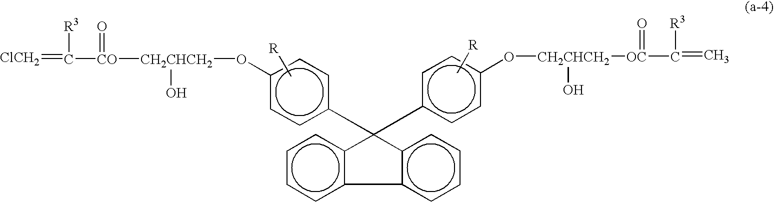

wherein R is defined as the above, R³ is H or CH₃.

Then Compound (a-4) is reacted with “one kind of multicarboxylic acids (or its anhydrides)” to obtain the alkali-soluble resin (A). For example, Compound (a-4) and dicarboxylic anhydride are heated and reacted in existence of an ester compound such as ethoxyethyl acetate or butoxyethyl acetate, and thus the alkali-soluble resin (A) having ethylenically unsaturated double bond and carboxyl group is obtained. The alkali-soluble resin (A) can be indicated by a general formula (A-1) (abbreviated as Resin (A-1));

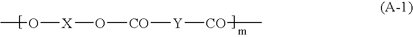

wherein m is an integer of 1 to 20; X can be indicated by a general formula (a-5) (abbreviated as Compound (a-5)),

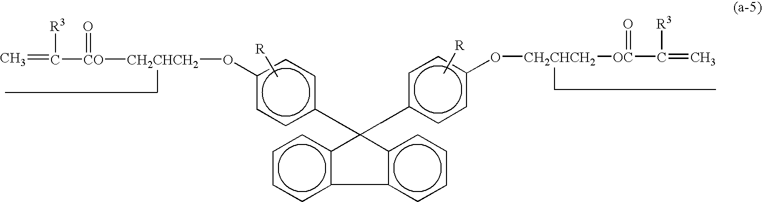

wherein R and R³ are defined as the above; Y is a residue of the dicarboxylic anhydride derived from the following compound of a general formula (a-6) (abbreviated as Compound (a-6)).

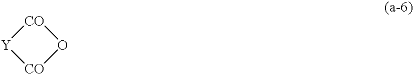

“One kind of the multicarboxylic acid (or its anhydrides)” above-mentioned in Method I means only one kind of dicarboxylic acid or its anhydrides, tricarboxylic acid or its anhydrides and tetracarboxylic acid or its dianhydrides can be used during reactions.

### Method II

Compound (a-4) and a “mixture” of dicarboxylic anhydride and tetracarboxylic dianhydride are heated and reacted in existence of an ester compound such as ethoxyethyl acetate or butoxyethyl acetate, and thus the alkali-soluble resin (A) having ethylenically unsaturated double bond and carboxyl group is obtained. The alkali-soluble resin (A) produced according to Method II can be indicated by a general formula (A-2) (abbreviated as Resin (A-2));

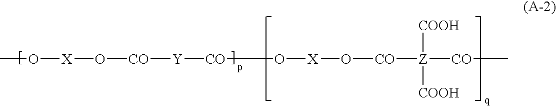

wherein X and Y are defined as the above, p and q are integers of 1 to 20; Z is a residue of the tetracarboxylic dianhydride derived from the following compound of a general formula (a-7) (abbreviated as Compound (a-7)).

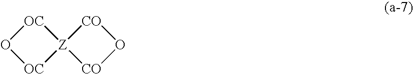

p and q are integers larger than 1, preferably 1˜20.

The above “p” and “q” represent degrees of polymerization, and the ratio p/q is preferably 1/99˜90/10, more preferably 5/95˜80/20.

The “mixture” aforementioned in Method II means the reaction is performed in existence of dicarboxylic anhydride and tetracarboxylic dianhydride.

### Method III

Compound (a-4) and tetracarboxylic dianhydride are heated and reacted in existence of an ester compound such as ethoxyethyl acetate or butoxyethyl acetate. Then dicarboxylic anhydride is added into the solution for further reaction, and thus the alkali-soluble resin (A) having ethylenically unsaturated double bond and carboxyl group is obtained. The alkali-soluble resin (A) produced by Method III can be indicated by a general formula (A-3) (abbreviated as Resin (A-3));

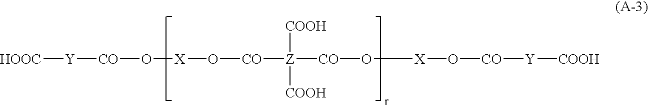

wherein X, Y and Z are defined as the above, r is an integer of 1 to 20.

For the above reactions according to Methods I-III, Compound (a-4) and multicarboxylic acid or its anhydrides are preferably reacted at 50˜130° C., more preferably 70˜120° C. The equivalent (hereinafter abbreviated as Eq) of anhydrous group of multicarboxylic anhydride is preferably at 0.4˜1.0 Eq based on 1 Eq of hydroxyl group of Compound (a-4), more preferably at 0.75˜1.0 Eq.

For the above reactions according to Methods II and III, mole ratio of dicarboxylic anhydride to tetracarboxylic dianhydride is preferably 1/99˜90/10, more preferably 5/95˜80/20.

### (B) Photopolymerizable Monomer

Amount of the photopolymerizable monomer (B) used in the present invention is generally 5˜220 parts by weight, preferably 10˜160 parts by weight, more preferably 15˜120 parts by weight, based on 100 parts by weight of the alkali-soluble resin (A).

The photopolymerizable monomer (B) in the present invention is a monomer having at least one ethylenically unsaturated double bond.

Examples of the photopolymerizable monomer (B) having one ethylenically unsaturated double bond are as follows: acrylamide, (meth)acryloylmorpholine, 7-amino-3,7-dimethyloctyl(meth)acrylate, isobutoxymethyl(meth)acrylamide, isobornyloxyethyl(meth)acrylate, isobornyl(meth)acrylate, 2-ethylhexyl(meth)acrylate, ethyl diethylene glycol(meth)acrylate, t-octyl(meth)acrylamide, diacetone(meth)acrylamide, dimethylaminoethyl(meth)acrylate, dodecyl(meth)acrylate, dicyclopentenyloxyethyl(meth)acrylate, dicyclopentenyl(meth)acrylate, N,N-dimethyl(meth)acrylamide, tetrachlorophenyl(meth)acrylate, 2-tetrachlorophenoxyethyl(meth)acrylate, tetrahydrofurfuryl(meth)acrylate, tetrabromophenyl(meth)acrylate, 2-tetrabromophenoxyethyl(meth)acrylate, 2-trichlorophenoxyethyl(meth)acrylate, tribromophenyl(meth)acrylate, 2-tribromophenoxyethyl(meth)acrylate, 2-hydroxyethyl(meth)acrylate, 2-hydroxypropyl(meth)acrylate, vinylcaprolactam, N-vinylpyrrolidinone, phenoxyethyl(meth)acrylate, pentachlorophenyl(meth)acrylate, pentabromophenyl(meth)acrylate, polyethylene glycol mono(meth)acrylate, polypropylene glycol mono(meth)acrylate and bornyl(meth)acrylate, and the like.

Examples of the photopolymerizable monomer (B) having two or more ethylenically unsaturated double bond are as follows: ethylene glycol di(meth)acrylate, dicyclopentenyl di(meth)acrylate, triethylene glycol diacrylate, tetraethylene glycol di(meth)acrylate, tris(2-hydroxyethyl)isocyanate di(meth)acrylate, tris(2-hydroxyethyl)isocyanante tri(meth)acrylate, caprolactone-modified tris(2-hydroxyethyl)isocyanante tri(meth)acrylate, trimethylolpropyl tri(meth)acrylate, ethyleneoxide (hereinafter abbreviated as EO) modified trimethylolpropyl tri(meth)acrylate, propyleneoxide(hereinafter abbreviated as PO) modified trimethylolpropyl tri(meth)acrylate, tripropylene glycol di(meth)acrylate, neopentyl glycol di(meth)acrylte, 1,4-butanediol di(meth)acrylate, 1,6-hexadiol di(meth)acrylate, pentaerythritol tri(meth)acrylate, pentaerythritol tetra(meth)acrylate, polyester di(meth)acrylate, polyethylene glycol di(meth)acrylate, dipentaerythritol hexa(meth)acrylate, dipentaerythritol penta(meth)acrylate, dipentaerythritol tetra(meth)acrylate, caprolactone-modified dipentaerythritol hexa(meth)acrylate, caprolactone-modified dipentaerythritol penta(meth)acrylate, ditrimethylolpropyl tetra(meth)acrylate, EO-modified bisphenol A di(meth)acrylate, PO-modified bisphenol A di(meth)acrylate, EO-modified hydrogenated bisphenol A di(meth)acrylate, PO-modified hydrogenated bisphenol A di(meth)acrylate, PO modified glycerol triacrylate, EO modified bisphenol F di(meth)acrylate, phenol novolac polyglycidyl ether (meth)acrylate, and the like.

Among these, trimethylolpropyl triacrylate, EO-modified trimethylolpropyl triacrylate, PO-modified trimethylolpropyl triacrylate, pentaerythritol triacrylate, pentaerythritol tetraacrylate, dipentaerythritol hexaacrylate, dipentaerythritol pentaacrylate, dipentaerythritol tetaacrylate, caprolactone-modified dipentaerythritol hexaacrylate, ditrimethylolpropyl tetraacrylate and PO modified glycerol triacrylate are preferred.

### (C) Photoinitiator

The photoinitiator (C) of the invention has a general structural formula (c-1),

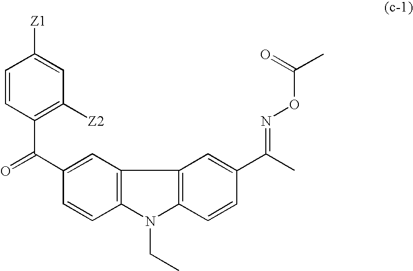

wherein Z₁ is selected from the group consisting of Ra, Rb—S and Rc-O, wherein each of Ra, Rb and Rc is independently H, alkyl or aryl; Z₂ is H, alkyl of C1-C4, or halide.

The amount of the photoinitiator (C) used in the present invention is generally 2˜120 parts by weight, preferably 5˜70 parts by weight, more preferably 10˜60 parts by weight, based on 100 parts by weight of the photopolymerizable monomer (B).

Preferred examples of the photoinitiator (C) include: Ethanone,1-[9-ethyl-6-(2-methylbenzoyl)-9H-carbazole-3-yl]-,1-(O-acetyl oxime) (CGI-242, manufactured by Ciba Specialty Chemicals, having a general suructual formula (c-1-1)), Ethanone,1-[9-ethyl-6-(2-chloro-4-benzyl thio benzoyl)-9H-carbazole-3-yl]-,1-(O-acetyl oxime) (manufactured by Asahi Denka Co., Ltd., having a general structural formula (c-1-2)).

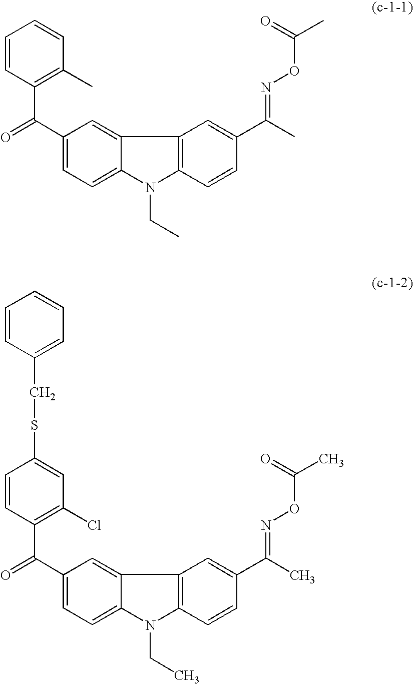

In the present invention, an additional photoinitiator (C′), such as acetophenone series compounds, may be used.

Examples of the acetophenone series compounds include: p-dimethyl amino-acetophenone, α,α′-dimethoxyazoxyacetophenone, 2,2′-dimethyl-2-phenylacetophenone, p-methoxy acetophenone, 2-methyl-1-(4-methylthiophenyl)-2-morpholinopropane-1-on and 2-benzyl-2-N,N-dimethylamino-1-(4-morpholinophenyl)-1-butanone.

The above photoinitiators (C′) can be used alone or in admixture of two or more. Among the above photoinitiators (C′), 2-methyl-1-(4-methylthiophenyl)-2-morpholinopropane-1-on and 2-benzyl-2-N,N-dimethylamino-1-(4-morpholinophenyl)-1-butanone are preferred.

The amount of the photoinitiators (C′) used in the present invention is generally 0.5˜60 parts by weight, preferably 1˜50 parts by weight, more preferably 2˜40 parts by weight, based on 100 parts by weight of the photopolymerizable monomer (B).

In the present invention, the photoinitiator (C) having a formula (c-1) and the photoinitiator (C′) of acetophenone series compounds are preferably used in combination, so as to obtain patterns having high resolution after coating, exposure and development.

Moreover, a photoinitiator (C″) can be used in addition to the above photoinitiator (C) and photoinitiator (C′). The photoinitiator (C″) can be biimidazole, such as 2,2′-bis(o-chlorophenyl)-4,4′,5,5′-tetraphenyl-biimidazole, 2,2′-bis(o-fluorophenyl)-4,4′,5,5′-tetraphenyl-biimidazole, 2,2′-bis(o-methylphenyl)-4,4′,5,5′-tetraphenyl-biimidazole, 2,2′-bis(o-methoxyphenyl)-4,4′,5,5′-tetraphenylbiimidazole, 2,2′-bis(p-methoxyphenyl)-4,4′,5,5′-tetraphenylbiimidazole, 2,2′-bis(2,2′,4,4′-tetramethoxyphenyl)-4,4′,5,5′-tetraphenyl-biimidazole, 2,2′-bis(2-chlorophenyl)-4,4′,5,5′-tetraphenylbiimidazole, 2,2′-bis(2,4-dichlorophenyl)-4,4′,5,5′-tetraphenyl-biimidazole and the like; Oxime, such as 1-(4-phenyl-thio-phenyl)-butane-1,2-dion2-oxime-O-benzoate, 1-(4-phenyl-thio-phenyl)-octane-1,2-dion2-oxime-O-benzoate (CGI-124, manufactured by Ciba Specialty Chemicals, having a general structural formula (c″-1)),

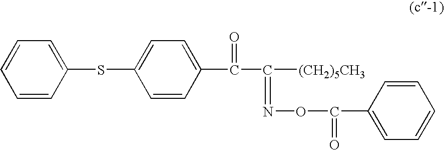

1-(4-phenyl-thio-phenyl)-octane-1-on oxime-O-acetate, 1-(4-phenyl-thio-phenyl)-butane-1-on oxime-O-acetate and the like; benzophenone, such as thioxanthone, 2,4-diethylthioxanthanone, thioxanthone-4-sulfone, benzophenone, 4,4′-bis(dimethylamino)benzophenone, 4,4′-bis(diethylamino)benzophenone and the like; α-diketone, such as benzyl, acetyl and the like; acyloin, such as benzoin and the like; acyloin ether, such as benzoin methylether, benzoin ethylether, benzoin isopropyl ether and the like; acylphosphineoxide, such as 2,4,6-trimethyl-benzoyl diphenylphosphineoxide, bis-(2,6-dimethoxy-benzoyl)-2,4,4-trimethylbenzyl phosphineoxide and the like; quinine, such as anthraquinone, 1,4-naphthoquinone and the like; halide, such as phenacyl chloride, tribromomethyl phenylsulfone, tris(trichloromethyl)-s-triazine and the like; peroxide, such as di-tertbutylperoxide and the like.

### (D) Solvent

The photosensitive composition for black matrix of the present invention comprises the alkali-soluble resin (A), the photopolymerizable monomer (B), photoinitiator (C), the solvent (D) and the black pigment (E) as essential components, and may optionally contain other additive components as required.

Said solvent (D) can be any solvent as long as they can dissolve the alkali-soluble resin (A), the photopolymerizable monomer (B) and the photoinitiator (C), and they are inert to the other components and have appropriate volatility.

The amount of solvent (D) used for preparing the photosensitive resin composition for black matrix in the present invention is generally 500˜3,500 parts by weight, preferably 800˜3,200 parts by weight, more preferably 1,000˜3,000 parts by weight, based on 100 parts by weight of said alkali-soluble resin (A).

Examples of the solvent (D) are as follows: (poly)alkylene glycol monoalkyl ether, such as ethylene glycol monomethyl ether, ethylene glycol monoethyl ether, diethylene glycol monomethyl ether, diethylene glycol monoethyl ether, diethylene glycol n-propyl ether, diethylene glycol n-butyl ether, triethylene glycol monomethyl ether, triethylene glycol monoethyl ether, propylene glycol monomethyl ether, propylene glycol monoethyl ether, dipropylene glycol monomethyl ether, dipropylene glycol monoethyl ether, dipropylene glycol n-propyl ether, dipropylene glycol n-butyl ether, tripropylene glycol monomethyl ether, tripropylene glycol monoethyl ether; (poly)alkylene glycol monoalkyl ether acetate, such as ethylene glycol monomethyl ether acetate, ethylene glycol monoethyl ether acetate, propylene glycol monomethyl ether acetate, propylene glycol monoethyl ether acetate and the like; ether, such as diethylene glycol dimethyl ether, diethylene glycol methyl ethyl ether, diethylene glycol diethyl ether, tetrahydrofuran; ketone, such as methyl ethyl ketone, cyclohexanone, 2-heptanone, 3-heptanone; alkyl lactate, such as methyl 2-hydroxypropionate and ethyl 2-hydroxypropionate; other esters, such as methyl 2-hydroxy-2-methylpropionate, ethyl2-hydroxy-2-methylpropionate, methyl 3-methoxypropionate, ethyl3-methoxypropionate, methyl3-ethoxypropionate, ethyl 3-ethoxypropionate, ethyl ethoxy acetate, ethyl hydroxy acetate, methyl 2-hydroxy-3-methylbutyrate, 3-methoxy butyl acetate, 3-ethoxybutyl acetate, 3-methyl-3-methoxybutyl acetate, 3-methyl-3-methoxybutyl propionate, ethyl acetate, n-propyl acetate, i-propyl acetate, n-butyl acetate, i-butyl acetate, n-amyl acetate, i-amyl acetate, n-butyl propionate, ethyl butyrate, n-propyl butyrate, i-propyl butyrate, n-butyl butyrate, methyl pyruvic acid ester, ethyl pyruvic acid ester, n-propyl pyruvic acid ester, methyl acetoacetate, ethyl acetoacetate and ethyl-2-oxobutyrate; aromatic hydrocarbons, such as toluene and xylene; carboxylic acid amides, such as N-methylpyrrolidone, N,N-dimethylformamide, N,N-dimethylacetoamide and the like. The solvents can be used along or in admixture of two or more. Among these solvents, the propylene glycol monomethyl ether acetate, diethylene glycol dimethyl ether and ethyl3-ethoxy propionate are preferred.

### (E) Black Pigment

The amount of pigment (E) used for preparing the photosensitive resin composition for black matrix in the present invention is generally 20˜500 parts by weight, preferably 40˜400 parts by weight, more preferably 60˜350 parts by weight, based on 100 parts by weight of the alkali-soluble resin (A).

The black pigment (E) of the present invention is required to have good heat resistance, light resistance and chemical resistance. Examples of the black pigment are as follows: organic black pigment, such as perylene black, cyanine black, aniline black; an approximately black pigment made by mixing two or more organic pigments selected from red, blue, green, purple, yellow, cyanine, magenta; inorganic pigment, such as carbon black, chromium oxide, ferric oxide, titanium black, graphite and the like. The pigments can be used along or in admixture of two or more.

The pigment (E) in the present invention can be used in combination with a dispersant as desired. The dispersant is, for example, a cationic, anionic, nonionic or amphoteric surfactant, or a silicone-based or fluorine-based surfactant in terms of composition.

Examples of the surfactant include polyoxyethylene alkyl ethers, such as polyoxyethylene lauryl ether, polyoxyethylene stearyl ether, polyoxyethylene oleyl ether, and the like; polyoxyethylene aryl ethers, such as polyoxyethylene octyl phenyl ether, polyoxyehtylene nonyl phenyl ether; polyethylene glycol dialkyl esters, such as polyethylene glycol dilaurate, polyethylene glycol distearate, and the like; sorbitan fatty acid esters; fatty acid modified polyesters; tertiary amine modified polyurethans. The following examples of surfactants can be used, such as: KP (manufactured by Shin-Etsu Chemical Industry Co., Ltd.), SF-8427 (manufactured by Toray Dow Corning Silicon), Polyflow (manufactured by Kyoei-Sha Yushi Kagaku Kogyo Co., Ltd.), F-Top (manufactured by Tochem Products Co., Ltd.), Megafac (manufactured by Dainippon Chemicals and Ink Co., Ltd.), Fluorade (manufactured by Sumitomo 3M Co., Ltd.), Asahi Guard and Surflon (manufactured by Asahi Glass Co., Ltd.), and the like. The surfactants can be used alone or in admixture of two or more.

To improve coatability of the present invention, the photosensitive resin composition can be used in combination with surfactants. The amount of the surfactants used in the present invention is generally 0˜6 parts by weight, preferably 0˜4 parts by weight, more preferably 0˜3 parts by weight, based on 100 parts by weight of said alkali-soluble resin (A). Examples of the surfactants are the same as the surfactants used in the pigment aforementioned.

The photosensitive composition of the present invention can contain other additives, such as fillers, polymers other than the alkali-soluble resin (A), adhesion agents, antioxidants, UV absorbents, anti-coagulants, cross-linking agent, and the like. The amount of the additives except cross-linking agent is generally 0˜10 parts by weight, preferably 0˜6 parts by weight, more preferably 0˜3 parts by weight, based on 100 parts by weight of the alkali-soluble resin (A). The amount of the cross-linking agent is generally 0˜100 parts by weight, preferably 0˜80 parts by weight, more preferably 0˜50 parts by weight, based on 100 parts by weight of said alkali-soluble resin (A).

Examples of these additives can be exemplified as follows: fillers, such as glass, alumina; polymers other than the alkali-soluble resin (A), such as polyvinyl alcohol, polyacrylic acid, polyethylene glycol monoalkyl ether, polyfluoro alkylacrylate and the like; adhesion agents, such as vinyltrimethoxysilane, vinyltriethoxysilane, vinyltris(2-methoxyethoxy)silane, N-(2-aminoethyl)-3-aminopropylmethyldimethoxysilane, N-(2-aminoethyl)-3-aminopropyltrimethoxy-silane, 3-aminopropyltriethoxysilane, 3-glycidyloxy propyltrimethoxysilane, 3-glycidyloxypropylmethyldimethoxysilane, 2-(3,4-epoxycyclohexyl)ethyltrimethoxy-silane, 3-chloropropylmethyldimethoxysilane, 3-chloropropyltrimethoxysilane, 3-methacryloxypropyltrimethoxysilane, 3-mercaptopropyltrimethoxysilane and the like; antioxidants, such as 2,2-thiobis(4-methyl-6-t-butylphenol), 2,6-di-t-butylphenol and the like; UV absorbents, such as 2-(3-t-butyl-5-methyl-2-hydroxyphenyl)-5-chlorobenzo triazole, alkoxybenzophenone and the like; and anti-coagulant, such as sodium polyacrylate; The cross-linking agent can be epoxy compounds or resins, such as 1031S and 157S-70 (manufactured by Japan Epoxy Resins Co., Ltd.).

The photosensitive resin composition for black matrix according to the present invention is formed by blending the above-mentioned components (A)-(E) in a mixer to obtain a solution, and the additives such as surfactant; adhesion agent or cross-linking agent can be added, optionally.

Then, the photosensitive resin composition for black matrix is coated on the substrate and then dried in low pressure to remove most of the solvent. After completely evaporate the residual solvent by pre-bake, a coating film is formed. Examples of coating process include spin coating, slit coating and roll coating. Operation conditions for low-pressure drying and pre-bake are dependent on kinds and dosages of the components used in the photosensitive resin composition. In general, low-pressure drying is carried out at 0˜200 mm-Hg for 1˜10 seconds, and pre-bake is carried out at 70° C.˜110° C. for 1˜15 minutes. Then, the coating film is exposed to UV light through a specific photo mask, and developed in a developer solution at 23±2° C. for 15 seconds to 5 minutes to dissolve and remove the un-exposed portions of the coating film, so as to give a desired pattern. The UV light used for this purpose can be g line, h line, i line and the like. The UV lamp is (ultra) high-pressure mercury lamp and metal halide lamp.

The substrate used to form the black matrix can be made from bare glass, soda glass, pyres glass, silica glass, and these glass coated with a transparent conductive film, or transparent electrode substrate used in solid state image pick up device.

The alkali developer is preferably an aqueous solution of sodium hydroxide, potassium hydroxide, sodium carbonate, sodium hydrogencarbonate, potassium carbonate, potassium hydrogencarbonate, sodium silicate, sodium methylsilicate, aqueous ammonia, ethylamine, diethylamine, dimethyl ethanolamine, tetramethylammonium hydroxide, tetraethylammonium hydroxide, choline, pyrrole, piperidine, 1,8-diaza-bicyclo(5,4,0)-7-undecene and the like. The concentration of alkali developer is 0.001 wt %˜10 wt %, preferably 0.005 wt %˜5 wt %, more preferably 0.01 wt %˜1 wt %.

After developed with the developer solution, the resulted pattern is sufficiently washed with water and dried with compressed air or compressed nitrogen.

Finally, it is post-baked with a heating device such as a hot plate at 150° C.˜250° C. for 5˜60 minutes or an oven at 150° C.˜250 for 15˜90 minutes. Through the above-mentioned procedures, the black matrix for LCD of the present invention is obtained.

In the present invention, the OD value of black matrix is generally greater than 4.0, preferably 4.0˜5.5, more preferably 4.2˜5.2. For the purpose of increase the OD value of black matrix, the dosage of pigment must be increased generally, and the undercut also occurs easily. In order to promote the OD value of black matrix and reduce the undercut, the photosensitive resin composition for black matrix is necessary to meet the following conditions: (1) the alkali-soluble resin (A) comprises a functional group having the formula (a-1); and (2) the photoinitiator (C) comprises a functional group having the formula (c-1).

The photosensitive resin composition of the present invention comprises alkali-soluble resin, photopolymerizable monomer, photoinitiator, solvent and black pigment. There are many ways to obtain higher OD value of black matrix, including higher dosage of pigment and/or reducing the particle size of the pigment. However, the white dot defect occurs easily after development while increasing the OD value greater than 4.0. The applicants have found that in order to reach the OD value greater than 4.0 without any white dot defect, the moisture content of the photosensitive resin composition has to be less than 3,000 ppm, preferably 2,800 ppm, more preferably 2,500 ppm.

### EXAMPLES AND COMPARATIVE EXAMPLES

The present invention will be further illustrated by the following examples.

### [Synthesis of the Alkali-Soluble Resin (A)]

### Synthesis Example A

A 500 ml separable flask equipped with a stirrer, a heater, a condenser, and a thermometer is introduced with air. Then a mixture comprising 100 parts by weight of bisphenolfluorene-based epoxy compound having formual (a-2) which epoxy equivalent (Eq) is 230, 0.3 part by weight of tetramethyl ammonium chloride, 0.1 part by weight of 2,6-di-t-butyl-p-cresol, 30 parts by weight of acrylic acid and 130 parts by weight of propylene glycol monomethyl ether acetate, was charged to the flask. These components were charged continuously in a rate of 25 parts by weight/minute. The temperature for reaction was maintained at 100° C.˜110° C., and the residence time of reaction were 15 hours. After reaction, a light yellow transparent solution, bisphenolfluorene-based epoxy(meth)acrylate (i.e., Compound (a-4)), with 50 wt % of solid content was obtained.

Then, an admixture comprising 100 parts by weight of Compound (a-4) obtained as the above, 25 parts by weight of propylene glycol monomethyl ether acetate, 13 parts by weight of benzophenone tetracarboxylic anhydride, and 6 parts by weight of 1,2,3,6-tetrahydro phthalic anhydrie was added into a 300 ml separable flask. The temperature for polymerization was maintained at 110° C.˜115° C., and the residence time were 2 hours. A yellow transparent solution, i.e., the alkali-soluble resin of formula (A-2), was obtained. The acid value of the resin was 98.0 mg KOH/g, weight average molecular weight was 4100, and p/q was 5/5.

After polymerization, the polymer solution was moved out from the separable flask, and the alkali-soluble resin (a) could be obtained while evaporating the solvent.

### Synthesis Example B

100 parts by weight of Compound (a-4) obtained in Synthesis Example a, 25 parts by weight of propylene glycol monomethyl ether acetate, and 13 parts by weight of benzophenone tetracarboxylic dianhydride were charged in a 300 ml separable flask. The temperature for reacton was 90° C.˜95° C., and the residence time were 2 hours. Disappearance of anhydrous group was confirmed with IR spectrum analysis. Then, 6 parts by weight of 1,2,3,6-tetrahydro phthalic anhydrie was added into the reaction solution. Temperature for reaction was 90° C.˜95° C., and the residence time were 4 hours. A light yellow transparent solution, i.e., the alkali-soluble resin of formula (A-3), was obtained. The acid value of the resin was 99.0 mg KOH/g, and weight average molecular weight was 3900.

After polymerization, the polymer solution was moved out from the separable flask, and the alkali-soluble resin (b) could be obtained while evaporating the solvent.

### Synthesis Example C

A 300 ml four-necked conical flask equipped with a stirrer, a heater, a condenser, and a thermometer is introduced with nitrogen. Then a mixture comprising 25 parts by weight of methacrylic acid monomer, 50 parts by weight of benzyl methacrylate monomer, 25 parts by weight of methyl acrylate monomer, 2.4 parts by weight of 2,2′-azobis-2-methyl butyronitrile as polymerization initiator, and 240 parts by weight of propylene glycol monomethyl ether acetate was charged in the flask in one shot. Temperature for polymerization was 100° C., and the residence time was 6 hours. After complete polymerization, the polymer solution was moved out from the flask, and the alkali-soluble resin (c) could be obtained while evaporating the solvent.

### [Preparation of the Photosensitive Resin Composition for Black Matrix]

### Example 1

100 parts by weight (based on dry matter) of the alkali-soluble resin (a) obtained in the above Synthesis Example a, 50 parts by weight of dipentaerythritol hexaacrylate (hereinafter abbreviated as B-1), 10 parts by weight of dipentaerythritol tetraacrylate (hereinafter abbreviated as B-2), 15 parts by weight of Ethanone,1-[9-ethyl-6-(2-methylbenzoyl)-9H-carbazole-3-yl]-, 1-(O-acetyloxime) (hereinafter abbreviated as C-1), 150 parts by weight of the black pigment C.I. 7 (hereinafter abbreviated as E-1), 1 part by weight of 3-methacryloxypropyltrimethoxysilane as adhesion agent, 15 parts by weight of 1031S (manufactured by Japan Epoxy Resins Co., Ltd.) as cross-linking agent were added into the flask. Then the solvents, 1,200 parts by weight of propylene glycol monomethyl ether acetate (hereinafter abbreviated as D-1) and 300 parts by weight of ethyl 3-ethoxy propionate (hereinafter abbreviated as D-2) were added into the flask and blended for dissolving the above components with a shaker. Then, the photosensitive resin composition for black matrix was obtained. The photosensitive resin composition was evaluated with the following analysis, and the results were listed in Table 1.

### Example 2

The procedures of Example 1 were repeated, except that types of the alkali-soluble resin (A) and the dosages of the photoinitiator (C) were changed as Table 1. The evaluation results were shown in Table 1

### Example 3

The procedures of Example 1 were repeated, except that the types and dosages of the photoinitiator (C) were changed as follows: 20 parts by weight of the photoinitiator (C-1), 5 parts by weight of 2-methyl-1-(4-methylthiophenyl)-2-morpholino-1-propanone (hereinafter abbreviated as C′-1) and 1,500 parts by weight of the solvent (D-1), but no cross-linking agent was added. The evaluation results were shown in Table 1.

### Example 4

The procedures of Example 2 were repeated, except that the types and dosages of the photoinitiator were changed as follows: 20 parts by weight of the photoinitiator (C-1), 7 parts by weight of 2-benzyl-2-N,N-dimethylamino-1-(4-morpholinophenyl)-1-butanone (hereinafter abbreviated as C′-2) and 1,500 parts by weight of the solvent (D-1), 180 parts by weight of pigment (E-1), but no adhesion agent was added. The evaluation results were shown in Table 1.

### Example 5

50 parts by weight (based on dry matter) of the alkali-soluble resin (a) and 50 parts by weight (based on dry matter) of the alkali-soluble resin (b) obtained in the above Synthesis Examples, 60 parts by weight of the photopolymerizable monomer (B-1), 20 parts by weight of compound (C-1), 5 parts by weight of compound (C′-1), 200 parts by weight of (E-1), 1 part by weight of 3-methacryloxypropyl trimethoxysilane as adhesion agent, 15 parts by weight of cross-linking agent 1031S (manufactured by Japan Epoxy Resins Co., Ltd.) were dissolved in 1,500 parts by weight of solvent (D-1) with a shaker. Then, the photosensitive resin composition for black matrix was obtained. The photosensitive resin composition was evaluated with the following analysis, and the results were listed in Table 1.

### Example 6

The procedures of Example 1 were repeated, except that the dosage of the pigment was changed and the solvent D was pretreated with molecular sieve 4A (pellet type) by agitation for 6 hours with a weight ratio of molecular sieves to solvent D being 2/100. After the pretreatment of solvent D, the molecular sieves were separated by filtration under a dry nitrogen atmosphere before the preparation of the photosensitive resin composition. The evaluation results were shown in Table 1.

### Example 7

The procedures of Example 6 were repeated, except that dosage of the pigment was changed. The evaluation results were shown in Table 1.

### Example 8

The procedures of Example 1 were repeated, except that the dosage of the pigment was changed, and the photosensitive resin composition was purged with nitrogen gas at least 2 hours to reduce moisture content. The loss of solvent during nitrogen gas purging was supplemented with purify solvent to retain the original solid content of the photosensitive resin composition. The evaluation results were shown in Table 1.

### Example 9

The procedures of Example 4 were repeated, except that the follows. (1) The dosage of the pigment was changed. (2) The solvent D was pretreated with molecular sieve 4A (pellet type) by agitation for 6 hours with a weight ratio of molecular sieves to solvent D being 2/100. After the pretreatment of solvent D, the molecular sieves were separated by filtration under a dry nitrogen atmosphere before the preparation of the photosensitive resin composition. (3) The photosensitive resin composition is treated with the molecular sieve 4A (pellet type) by agitation for 12 hours with the weight ratio of molecular sieves to photosensitive resin composition being 3/500. After pretreatment of the photosensitive resin composition, the molecular sieves were separated by filtration under a dry nitrogen atmosphere. The evaluation results were shown in Table 1.

### Example 10

The procedures of Example 9 were repeated, except that the photosensitive resin composition was further purged with nitrogen gas at least 2 hours to reduce moisture content. The loss of solvent during nitrogen purging was supplemented with purify solvent to retain the original content of the photosensitive resin composition. The evaluation results were shown in Table 1. The white dot defect inspected by optical microscope was shown in following drawing. The magnification of the drawing was 50 times.

### Comparative Example 1

100 parts by weight (based on dry matter) of the alkali-soluble resin (c) obtained in the above Synthesis Example, 50 parts by weight of (B-1), 10 parts by weight of (B-2), 20 parts by weight of (C′-2), 20 parts by weight of 4,4′-bis(diethylamino)benzophenone (hereinafter abbreviated as C″-1), 20 parts by weight of 2,2′-bis(o-chlorophenyl)-4,4′,5,5′-tetraphenyl-biimidazole (hereinafter abbreviated as C″-2), 150 parts by weight of (E-1), 1 part by weight of 3-methacryloxypropyltrimethoxysilane as adhesion agent, 15 parts by weight of crosslinker 1031S (manufactured by Japan Epoxy Resins Co., Ltd.) were dissolved in 1,500 parts by weight of solvent (D-1) with a shaker. Then, the photosensitive resin composition for black matrix was obtained. The photosensitive resin composition was evaluated with the following analysis, and the results were listed in Table 1. The white dot defect inspected by optical microscope was shown in following drawing. The magnification of the drawing was 50 times.

### Comparative Example 2

The procedures of Comparative Example 1 were repeated, except that the type and dosage of the photoinitiator (C) were changed to 20 parts by weight of the photoinitiator (C-1). The evaluation results were shown in Table 1.

### Comparative Example 3

The procedures of Example 1 were repeated, except that the kind and dosage of the photoinitiator (C) were changed to 20 parts by weight of 1-(4-phenyl-thio-phenyl)-octane-1,2-dion2-oxime-O-benzoate (CGI-124, manufactured by Ciba, hereinafter abbreviated as C″-3) and 1,500 parts by weight of the solvent (D-1) and 180 parts by weight of the pigment (E-1). The evaluation results were shown in Table 1.

### Comparative Example 4

The procedures of Comparative Example 1 were repeated, except that the type of the alkali-soluble resin was changed and 200 parts by weight of the pigment (E-1). The evaluation results were shown in Table 1.

### Evaluation Method

### 1. OD Value (Optical Density Value)

The photosensitive resin composition was coated on a 100 mm×100 mm glass substrate by the spin-coating process (equipment produced by ShinKo trade., MS-A150), and then dried with the low pressure drying process at 100 mmHg for 5 seconds. Then the coating film was pre-baked at 85° C. for 3 minutes to form a pre-baked film of 2 μm thickness.

The pre-baked film obtained in the above photosensitivity evaluation was iradiated with UV (manufactured by Canon Inc., PLA-501F) in 300 mJ/cm² through a photo mask. After developed in a developer solution at 23° C. for 2 minutes, the film was washed with pure water. Then, the film was post-baked at 200° C. for 40 minutes to form a desired pattern of 1 μm thickness on the glass substrate. The O.D value can be calculated by following equations.

O.D=−log(I/I₀)

where I₀ is the intensity of the incident light and I is the intensity of the light coming out of the sample.

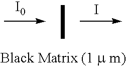

### 2. Undercut

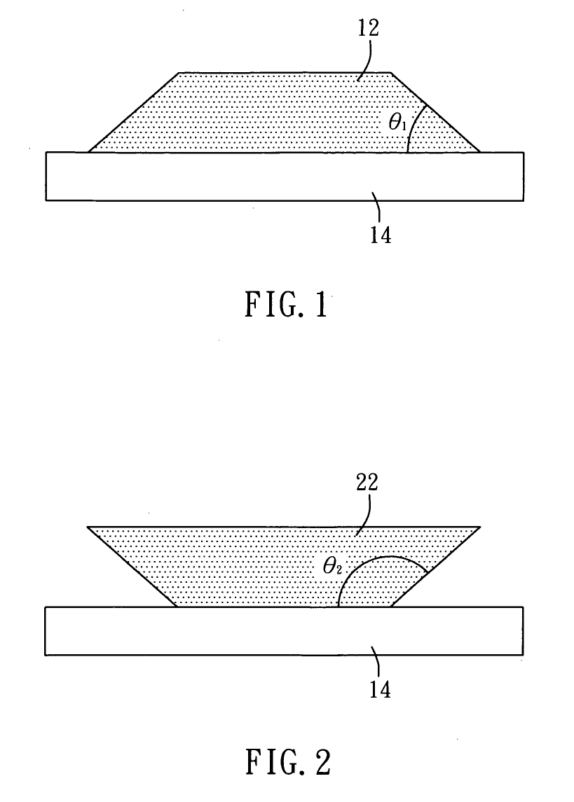

The pattern obtained in the above O.D value evaluation was observed under scanning electron microscope (SEM) to determine cross-sectional shape of edge profile.
◯: no undercut (as shown in FIG. 1, the angle θ₁ of the pattern (12) relative to the substrate (14) is below 90 degrees.)
×: undercut (as shown in FIG. 2, the angle θ₂ of the pattern (22) relative to the substrate (14) is larger than 90 degrees.)
   3. The Moisture Content of Photosensitive Resin Composition (unit:ppm)

The photosensitive resin composition is put into the flask of the Mettler moisture content titrater (E665 type), then it is titrated with Karl Fischer reagent SS (hereafter referred to as “KF reagent SS”, titer=0.7˜1.0 mgH₂O/milliliter), and the moisture content of the photosensitive resin composition can be calculated by the following formula.

Moisture content (ppm)=[The titer of KF reagent SS(mg H₂O/ml)×The amount of KF reagen SS titrated (ml)/The amount of photosensitive resin composition(mg)]×10⁶

### 4. White Dot Defect

The film of the photosensitive resin composition after development obtained in the above OD value evaluation was inspected with optical microscope and the number of white dot defect was counted. The evaluation based on the pattern of the 100 mm×100 mm Glass Substrate was shown as follows.
◯: Number of white dot is 0
Δ: Number of white dot is 1˜3
×: Number of white dot is above 4

The results according to the above evaluations are listed in Table 1.

While the present invention is illustrated with the preferred embodiments aforementioned, scope of the invention is not thus limited and should be determined in accordance with the appended claims.

TABLE 1

| | | Comparative Example | | | |
|---|---|---|---|---|---|
| Component (parts by weight) | | 1 | 2 | 3 | 4 |
| Alkali-soluble | a | | | 100 | 100 |
| resin (A) | b | | | | |
| | c | 100 | 100 | | |
| Photopolymerizable | B-1 | 50 | 50 | 50 | 50 |
| monomer (B) | B-2 | 10 | 10 | 10 | 10 |
| Photoinitiator (C) | C-1 | | 20 | | |
| Photoinitiator (C′) | C′-1 | | | | 1 |
| | C′-2 | 20 | | | 20 |
| Photoinitiator (C″) | C″-1 | 20 | | | 20 |
| | C″-2 | 20 | | | 20 |
| | C″-3 | | | 20 | |
| Solvent (D) | D-1 | 1500 | 1500 | 1500 | 1500 |
| | D-2 | | | | |
| Pigment (E) | E-1 | 150 | 150 | 180 | 200 |
| Additive | Adhesion | 1 | 1 | 1 | 1 |
| | agent | | | | |
| | Cross- | 15 | 15 | 15 | 15 |
| | linking | | | | |
| | agent | | | | |

| | | | | |
|---|---|---|---|---|
| OD value | 3.7 | 3.7 | 4.0 | 4.2 |
| Moisture Content | 3400 | 3400 | 3700 | 4000 |
| Undercut | X | X | X | X |
| White Dot Defect | X | X | X | X |

What is claimed is:

1. A photosensitive resin composition for black matrix comprising:
(A) an alkali-soluble resin including a functional group having a general formula (a-1), 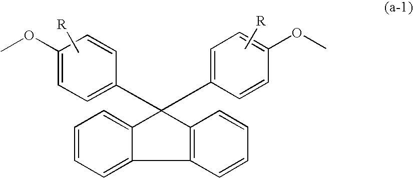
wherein each of R is independently H, linear or branch alkyl of C1-C5, phenyl or halogen;
(B) a photopolymerizable monomer, said photopolymerizable monomer having at least one ethylenically unsaturated double bond and being 5˜220 parts by weight based on 100 parts by weight of said alkali-soluble resin;
(C) a photoinitiator having a general formula (c-1), 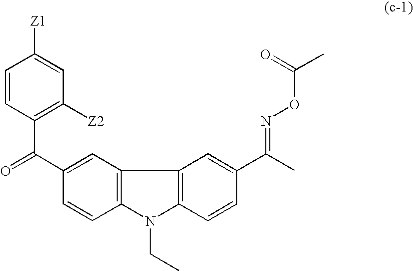
wherein Z₁ is selected from the group consisting of Ra, Rb—S and Rc-O, wherein each of Ra, Rb, Rc is independently H, alkyl or aryl; Z₂ is H, alkyl of C1-C4 or halide, said photoinitiator being 2˜120 parts by weight based on 100 parts by weight of said photopolymerizable monomer;
(D) a solvent, said solvent being 500˜3,500 parts by weight based on 100 parts by weight of said alkali-soluble resin; and
(E) a black pigment, said black pigment being 20˜500 parts by weight based on 100 parts by weight of said alkali-soluble resin;
wherein the moisture content of said photosensitive resin composition is less than 3,000 ppm, and the optical density value of said black matrix is greater than 4.0.

2. The photosensitive resin composition for a black matrix as claimed in claim 1 further comprising an acetophenone photoinitiator (C′), said acetophenone photoinitiator being 0.5˜60 parts by weight, based on 100 parts by weight of said photopolymerizable monomer.

3. The photosensitive resin composition for a black matrix as recited in claim 2, wherein said acetophenone photoinitiator (C′) is 1˜50 parts by weight based on 100 parts by weight of said photopolymerizable monomer.

4. The photosensitive resin composition for a black matrix as recited in claim 2, wherein said acetophenone photoinitiator (C′) is 2˜40 parts by weight based on 100 parts by weight of said photopolymerizable monomer.

5. The photosensitive resin composition for a black matrix as recited in claim 1, wherein said photoinitiator (C) is 5˜70 parts by weight based on 100 parts by weight of said photopolymerizable monomer.

6. The photosensitive resin composition for a black matrix as recited in claim 1, wherein said solvent is 800˜3200 parts by weight based on 100 parts by weight of said alkali-soluble resin.

7. The photosensitive resin composition for a black matrix as recited in claim 1, wherein said solvent is 1000˜3000 parts by weight based on 100 parts by weight of said alkali-soluble resin.

8. The photosensitive resin composition for a black matrix as recited in claim 1, wherein said pigment is 40˜400 parts by weight based on 100 parts by weight of said alkali-soluble resin.

9. The photosensitive resin composition for a black matrix as recited in claim 1, wherein said pigment is preferably 60˜300 parts by weight based on 100 marts by weight of said alkali-soluble resin.

10. The photosensitive resin composition for a black matrix as recited in claim 1, wherein said the optical density value of black matrixis is 4.0˜5.5.

11. The photosensitive resin composition for a black matrix as recited in claim 1, wherein said the optical density value of black matrixis is 4.2˜5.2.

12. The photosensitive resin composition for a black matrix as recited in claim 1, wherein said moisture content of said photosensitive resin composition is less than 2800 ppm.

13. The photosensitive resin composition for a black matrix as recited in claim 1, wherein said moisture content of said photosensitive resin composition is less than 2500 ppm.
